(19) United States
(12) Patent Application Publication
(10) Pub. No.: US 2013/0170134 A1
(43) Pub. Date: Jul. 4, 2013

(54) SERVER SYSTEM WITH FAN SPEED CONTROL AND SERVERS THEREOF

(71) Applicants: CHIH-CHUNG SHIH, Tu-Cheng (TW); CHUN-MING CHEN, Tu-Cheng (TW)

(72) Inventors: CHIH-CHUNG SHIH, Tu-Cheng (TW); CHUN-MING CHEN, Tu-Cheng (TW)

(73) Assignee: HON HAI PRECISION INDUSTRY CO., LTD., Tu-Cheng (TW)

(21) Appl. No.: 13/587,945

(22) Filed: Aug. 17, 2012

(30) Foreign Application Priority Data
Dec. 30, 2011 (TW) 100149854

(51) Int. Cl. H05K 7/20; G06F 1/20

(52) U.S. Cl. 361/679.48

(57) ABSTRACT

A server system includes a server cabinet, several servers, several fan groups coupled to a rear side of the server cabinet, and several fan control boards each connected to a group of the servers and a corresponding one of the fan groups. Each server includes several electronic components, a detecting module to detect performance characteristics of the electronic components, a comparison module to obtain a rotation speed according to the performance characteristics, and an executing module to convert the rotation speed into a fan speed control signal. Each fan group corresponds to a group of the servers. When the fan control board receives fan speed control signals from the servers, the fan control board converts the fan speed controls into an electrical signal to the fan group, thereby controlling the fan group to rotate at a corresponding speed to satisfy heat dissipation needs of the servers.

### BACKGROUND

1. Related Applications

Related subject matter is disclosed in a co-pending U.S. patent application with Attorney Docket Number US41402 and titled SERVER SYSTEM WITH FAN SPEED CONTROL, filed on Dec. 27, 2011which has the same assignee as the current application.

2. Technical Field

The present disclosure relates to a server system capable of controlling rotation speeds of the fans and servers thereof.

3. Description of Related Art

Server systems are commonly used to process and store data or information in networks. The server system includes a server cabinet and a number of servers accommodated in the server cabinet. A number of fans are arranged in the back of the server cabinet for cooling the servers during operation. Although conventional server systems satisfy basic requirements, a new type of server system is still desired.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a back view of a server system, partially cut away, in accordance with an exemplary embodiment.

FIG. 2 is a block diagram of the server system of FIG. 1.

FIG. 3 is a block diagram of a server of the server system of FIG. 1.

### DETAILED DESCRIPTION

Embodiments of the present disclosure are now described in detail, with reference to the accompanying drawings.

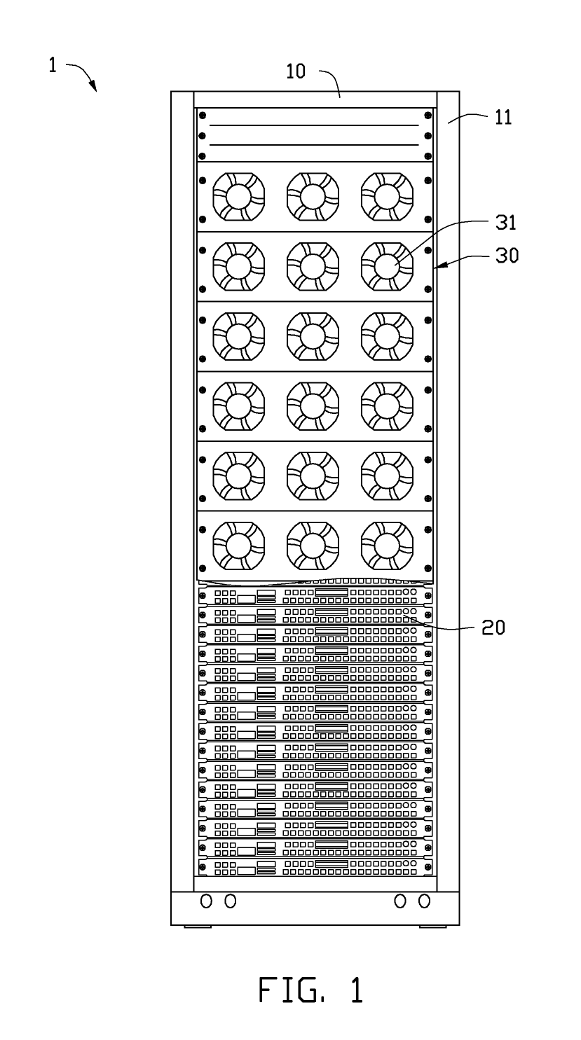

Referring to FIG. 1, a back view of a server system 1 according to an exemplary embodiment is illustrated. The server system 1 includes a server cabinet 10 with two parallel racks 11, a number of servers 20 located between the two racks 11, and a number of fan groups 30 coupled to a rear side of the server cabinet 10. In the embodiment, the length of the rack 11 is about 42 U (1 U =44.45 mm) or 48 U in height and can accommodate 42 to 48 servers.

The fan groups 30 are coupled to a rear side of the server cabinet 10 and each include a number of fans 31 to provide a horizontal airflow for cooling the corresponding servers 20. Each fan group 30 may include three, four, or five fans 31 arranged in a row, and the size of each fan 31 may be 92 mm*92 mm or 120 mm*120 mm.

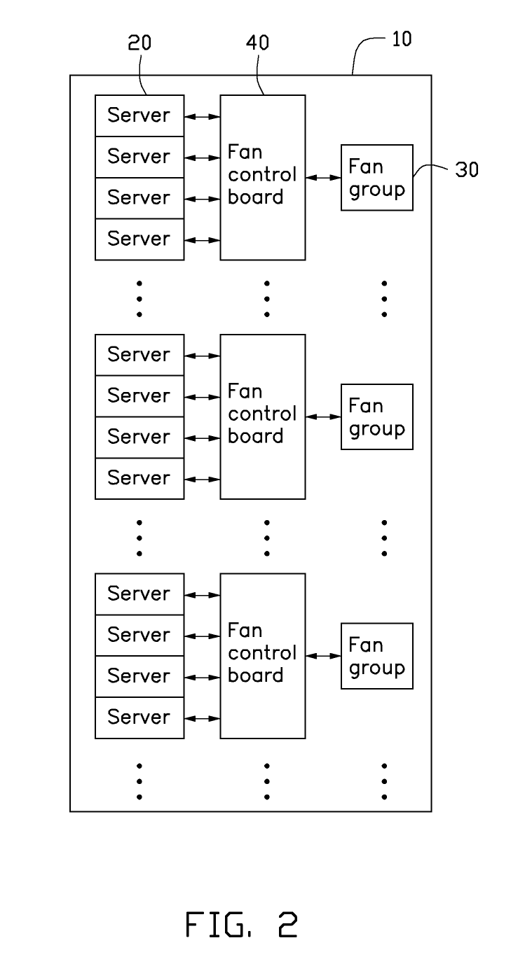

Referring also to FIG. 2, the server system 1 further includes a number of fan control boards 40 each of which is connected to four servers 20 for receiving fan speed control signals from those four servers 20, and a fan group 30 which is aligned with the four servers 20. In the embodiment, the fan control board 40 is connected to the fan server 20 via a pulse width modulation (PWM) cable or an integrated platform management bus. When the fan control board 40 receives one or more fan speed control signals from the corresponding servers 20, the fan control board 40 will control rotation speed of the corresponding fan group 30 accordingly to dissipate heat produced by the servers 20. In an exemplary embodiment, the fan control boards 40 can be integrated on a circuit board.

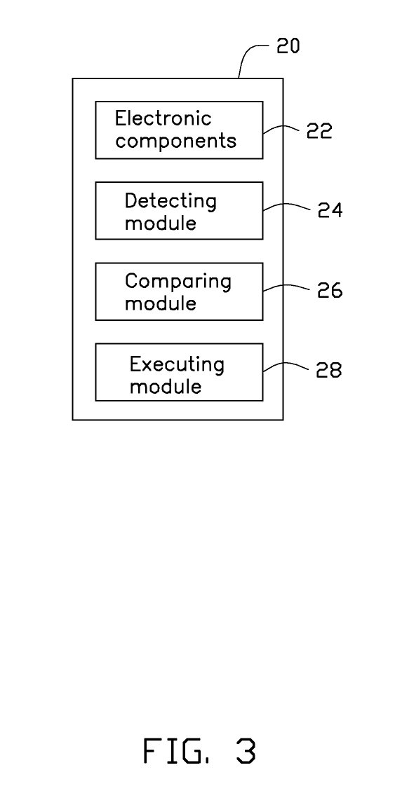

Referring also to FIG. 3, each server 20 includes a number of electronic components 22, a detecting module 24, a comparing module 26, and an executing module 28. The electronic components 22 may include for example, a processor, a memory unit, a hard disk, a network chip, and a direct current (DC) converter.

The detecting module 24 detects and/or measures a number of performance characteristics of the electronic components 22. In the embodiment, the performance characteristics may include such things as operating temperatures, usage rates, and data accessing speeds of the electronic components.

The comparing module 26 obtains a rotation speed according to the performance characteristics detected by the detecting module 24. In the embodiment, the comparing module 26 may obtain the rotation speed from a table that includes a number of rotation speeds corresponding to various possible performance measurements of the performance characteristics.

The executing module 28 converts the rotation speed to a fan speed control signal which is transmitted to the fan control board 40, thereby controlling the corresponding fan group 30 to rotate at a corresponding speed to satisfy heat dissipation needs of the servers 20.

While various embodiments have been described and illustrated, the disclosure is not to be constructed as being limited thereto. Various modifications can be made to the embodiments by those skilled in the art without departing from the true spirit and scope of the disclosure as defined by the appended claims.

What is claimed is:

1. A server system comprising:
a server cabinet;
a plurality of servers each comprising:
a plurality of electronic components;
a detecting module to detect a plurality of performance characteristics of the plurality of electronic components;
a comparison module to obtain a rotation speed according to the plurality of performance characteristics provided by the detecting module; and
an executing module to convert the rotation speed provided by the comparison module into a fan speed control signal;
a plurality of fan groups coupled to a rear side of the server cabinet and each comprising a plurality of fans to provide a horizontal airflow; and
a plurality of fan control boards each connected to several of the plurality of servers and one of the plurality of fan groups which is aligned with the several of the plurality of servers, wherein when the fan control board receives one or more fan speed control signals from the several of the plurality of servers, the fan control board converts the fan speed controls into an electrical signal to the fan group, thereby controlling the one of the plurality of fan groups to rotate at a corresponding speed to satisfy heat dissipation needs of the several of the plurality of servers.

2. The sever system as described in claim 1, wherein the server cabinet comprises two parallel racks, and the plurality of servers are located between the two racks.

3. The sever system as described in claim 2, wherein the racks is about 42 U in height and is able to accommodate 42 servers.

4. The sever system as described in claim 2, wherein the racks is about 48 U in height and is able to accommodate 48 servers.

5. The sever system as described in claim 1, wherein each fan group comprises three, four, or five fans arranged in a row.

6. The sever system as described in claim 5, wherein the size of each fan is 92 mm*92 mm.

7. The sever system as described in claim 5, wherein the size of each fan is 120 mm*120 mm.

8. The sever system as described in claim 1, wherein the plurality of fan control boards are integrated on a circuit board.

9. The sever system as described in claim 1, wherein the comparing module obtains the rotation speed from a table that comprises a number of rotation speeds corresponding to various possible performance measurements of the plurality of performance characteristics.

10. The sever system as described in claim 1, wherein the plurality of electronic components comprises a processor, a memory unit, a hard disk, a network chip, and a direct current (DC) converter, and the plurality of performance characteristics comprise such things as operating temperatures, usage rates, and data accessing speeds of the electronic components.

11. The sever system as described in claim 1, wherein the plurality of fan control boards are connected to the plurality of servers via a plurality of pulse width modulation (PWM) cables.

12. The sever system as described in claim 1, wherein the plurality of fan control boards are connected to the plurality of servers via a plurality of integrated platform management buses.

13. A server applied to a server system which comprises at least one fan control board connected to the server, the server comprising:
a plurality of electronic components;
a detecting module to detect a plurality of performance characteristics of the plurality of electronic components;
a comparison module to obtain a rotation speed according to the plurality of performance characteristics provided by the detecting module; and
an executing module to convert the rotation speed provided by the comparison module into a fan speed control signal which is transmitted to the at least one fan control board.

14. The sever as described in claim 13, wherein the comparing module obtains the rotation speed from a table that comprises a number of rotation speeds corresponding to various possible performance measurements of the plurality of performance characteristics.

15. The sever as described in claim 13, wherein the plurality of electronic components comprises a processor, a memory unit, a hard disk, a network chip, and a direct current (DC) converter, and the plurality of performance characteristics comprise such things as operating temperatures, usage rates, and data accessing speeds of the electronic components.

16. The sever as described in claim 13, wherein the at least one fan control board is connected to the plurality of servers via a plurality of pulse width modulation cables.

17. The sever as described in claim 13, wherein the at least one fan control board is connected to the plurality of servers via a plurality of integrated platform management buses.
